(19) United States
(12) Patent Application Publication
(10) Pub. No.: US 2013/0075880 A1
(43) Pub. Date: Mar. 28, 2013

(54) PACKAGING STRUCTURE

(71) Applicants: KUO-CHIANG CHEN, New Taipei City (TW); ARTHUR SHAOYAN RONG, Taipei City (TW); CHEN HSING LIU, Taoyuan County (TW); YEN-YI CHEN, New Taipei City (TW)

(72) Inventors: KUO-CHIANG CHEN, New Taipei City (TW); ARTHUR SHAOYAN RONG, Taipei City (TW); CHEN HSING LIU, Taoyuan County (TW); YEN-YI CHEN, New Taipei City (TW)

(73) Assignee: FORTUNE SEMICONDUCTOR CORPORATION, NEW TAIPEI CITY (TW)

(21) Appl. No.: 13/244,344

(22) Filed: Sep. 24, 2011

(51) Int. Cl. H01L 23/495

(52) U.S. Cl. 257/666; 257/E23.031

(57) ABSTRACT

A packaging structure comprises a first leadframe, a second leadframe, two grounding pins, two first pins, a plurality of first wires, a plurality of second wires, and a package body. The second leadframe is coupled to the drains of a first power transistor and a second power transistor. The two grounding pins are adjacent together and coupled to the first leadframe. The two first pins are coupled to the source of the second power transistor. The two first pins are connected together through a conductive region for increasing capability of loading current. The plurality of first wires is coupled between the source of the second power transistor and the first pin to decrease the internal resistance of the second power transistor. The plurality of second wires is coupled between the first leadframe and the source of the first power transistor to decrease the internal resistance of the first power transistor.

### BACKGROUND OF THE INVENTION

1. Field of the Invention

The present invention relates to a packaging structure; in particular, to a packaging structure for a lithium-ion battery protection circuit.

2. Description of Related Art

Please refer to 1, FIG. 1 shows a circuit diagram of a traditional single cell lithium-ion battery protection circuit. At present, the single cell lithium-ion battery is mainly composed of a lithium-ion cell and a single cell lithium-ion battery protection circuit board 1. The single cell lithium-ion battery protection circuit board 1 comprises resistors R1, R2, a capacitor C1, and a circuit board with an integrated circuit 10 cooperated with a first power transistor M1 and a second power transistor M2, as shown in FIG. 1. The packaging structure 11 of the integrated circuit 10 is often packaged by the package of Small Outline Transistor with six pins (SOT-26). The first power transistor M1 and the second power transistor M2 are power MOSFET transistor, and the first power transistor M1 and the second power transistor M2 are often packaged by the Thin-Shrink Small Outline Package with eight pins (TSSOP-8). The load is electrically coupled to pins BATP, BATN for obtaining electricity.

Details for the connections of the integrated circuit 10 packaged by the packaging structure 11, the first power transistor M1 and the second power transistor M2 package by the packaging structure 12 are described as follows. The integrated circuit 10 has pins VCC, GND, OD, OC, CS. The pins VCC, GND are for electrically coupled to the lithium-ion cell, and the pins OD, OC are electrically coupled to controlling terminals (gates) of the first power transistor M1 and the second power transistor M2 separately. The pin CS is a detecting terminal for over-current protection of the integrated circuit 10. However, the packaging manner of packaging the integrated circuit 10 and power transistors (M1, M2) separately may have higher manufacturing cost and occupy a larger packaging area.

### SUMMARY OF THE INVENTION

The object of the present invention is to provide a packaging structure for improving the stability and the manufacturing yield rate of the lithium-ion battery protection circuit, and for cutting down the packaging and testing cost.

In order to achieve the aforementioned objects, according to an embodiment of the present invention, a packaging structure is offered. The packaging structure comprises a first leadframe, a second leadframe, two grounding pins, two first pins, a plurality of the first conductive wires, a plurality of the second conductive wires, and a packaging body. The first leadframe is for disposing an integrated circuit. The second leadframe is for disposing a first power transistor and a second power transistor, and electrically coupled to drains of the first power transistor and the second power transistor. The two grounding pins are electrically coupled to the first leadframe, and the two grounding pins are adjacent to each other. The two first pins are electrically coupled to a source of the second power transistor, and the two first pins connect to each other through a conductive region, wherein the conductive region is for increasing the capacity of the current loading of the two first pins. The plurality of first conductive wires is electrically coupled between a source of the second power transistor and the two first pins, for reducing the internal resistance of the second power transistor. The plurality of second conductive wires is electrically coupled between the first leadframe and a source of the first power transistor, for reducing the internal resistance of the first power transistor. The packaging body is for covering the first leadframe, the second leadframe, the plurality of first conductive wires, the plurality of second conductive wires, the integrated circuit, the first power transistor, and the second power transistor, and partially covering the two grounding pins and the two first pins.

In summary, the packaging structure of the present invention simplified the traditional protection circuit for the single cell lithium-ion battery. The associated cost may be cut down by packaging the power transistors with the integrated circuit. Therefore, the mentioned packaging structure is more competitive in the market.

In order to further the understanding regarding the present invention, the following embodiments are provided along with illustrations to facilitate the disclosure of the present invention.

### BRIEF DESCRIPTION OF THE DRAWINGS

FIG. 1 shows a circuit diagram of a traditional single cell lithium-ion battery protection circuit;

FIG. 2A shows a schematic diagram of contact pads of a packaging structure of an integrated circuit according to an embodiment of the present invention;

FIG. 2B shows a top view of pins of a first power transistor and a second power transistor according to an embodiment of the present invention;

FIG. 2C shows a bottom view of pins of a first power transistor and a second power transistor according to an embodiment of the present invention;

FIG. 2D shows a perspective diagram of a packaging structure according to an embodiment of the present invention;

FIG. 3 shows a schematic diagram of the four-wire measurement according to an embodiment of the present invention;

FIG. 4A shows a top view of pins of a first power transistor and a second power transistor according to another embodiment of the present invention;

FIG. 4B s shows a perspective diagram of a packaging structure according to another embodiment of the present invention.

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended drawings.

[An Embodiment of the Packaging Structure]

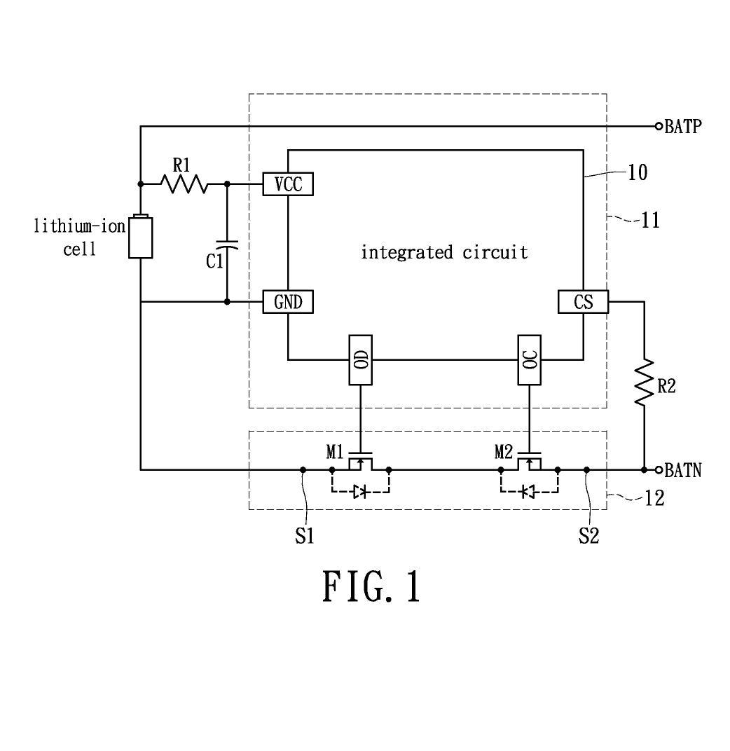

Please refer to FIG. 1 again; this embodiment packages the integrated circuit 10, the first power transistor M1, and the second power transistor M2 in a single packaging structure. For convenient to understand the packaging structure of this embodiment, firstly explaining the pins and contact pads of the integrated circuit 10, the first power transistor M1 and the second power transistor M2.

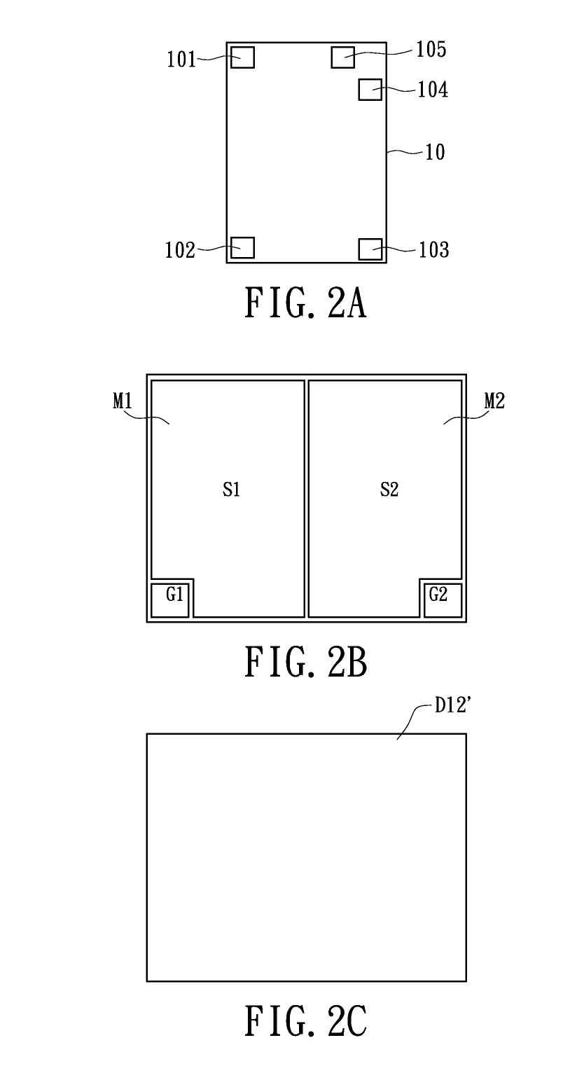

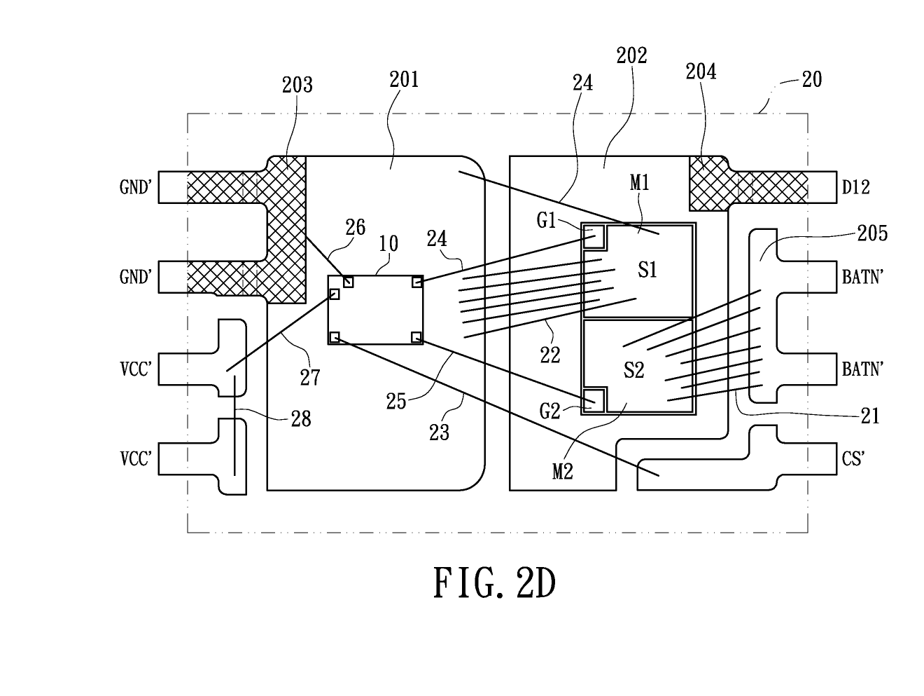

Please refer to FIG. 1 and FIG. 2A, FIG. 2A shows a schematic diagram of contact pads of a packaging structure of an integrated circuit according to an embodiment of the present invention. In FIG. 2A, a first contact pad 101 corresponds to the pin CS. A first controlling contact pad 103 and a second controlling contact pad 102 correspond to the pin OD and the pin OC of the integrated circuit 10 respectively. A grounding contact pad 104 and a power contact pad 105 correspond to the pin GND and the pin VCC of the integrated circuit 10.

Please refer to FIG. 1 and FIG. 2B, FIG. 2B shows a top view of pins of a first power transistor and a second power transistor according to an embodiment of the present invention. A source S1 of the first power transistor M1 has a larger area for passing a large current. Comparing to the source S1 of the first power transistor M1, a controlling terminal (i.e. the gate G1) of the first power transistor M1 has a smaller area. Similarly, the area of a source S2 of the second power transistor M2 is larger than that of a gate G2 for passing a large current. In addition, the gate G1 and the gate G2 are configured to be distant from each other. It should be notice that, in the manufacturing process, the first power transistor M1 and the second power transistor M2 are connected as a single chip.

Please refer to FIG. 1 and FIG. 2C, FIG. 2C shows a bottom view of pins of a first power transistor and a second power transistor according to an embodiment of the present invention. The drains of the first power transistor M1 and the second power transistor M2 share a contact pad D12′ for passing a larger current.

Please refer to FIG. 1 and FIG. 2D, FIG. 2D shows a perspective diagram of a packaging structure according to an embodiment of the present invention. A packaging structure 2 of this embodiment is a Thin-Shrink Small Outline Package with eight pins (TSSOP-8), the packaging structure 2 mainly comprises a first leadframe 201, a second leadframe 202, two grounding pins GND′, two first pins BATN′, a plurality of first conductive wires 21, a plurality of second conductive wires 22, and conductive glue 203, 204. Additionally, the packaging structure 2 further comprises two power pins VCC′, a second pin D12, a third pin CS′, a third conductive wire 23, a fourth conductive wire 24, a fifth conductive wire 25, a sixth conductive wire 26, a seventh conductive wire 27, and a conductive wire 28.

The first leadframe 201 is for disposing the integrated circuit 10. The second leadframe 202 is for disposing the first power transistor M1 and the second power transistor M2, and for being electrically coupled to drains of the first power transistor M1 and the second power transistor M2 through the contact pad D12′. The configuration of the first power transistor M1 and the second power transistor M2 is having the gate G1 and the gate G2 being close to the first leadframe 201. The two grounding pins GND′ are electrically coupled to the first leadframe 201, and the two grounding pins GND′ are adjacent to each other. The two first pins BATN′ are for being electrically coupled to the source S2 of the second power transistor M2. The two first pins BATN′ are connected with each other through a conductive region 205, and the conductive region 205 is for increasing the capability of the loading current of the two first pins BATN′. The plurality of first conductive wires 21 is for being electrically coupled between the source S2 and the two first pins BATN′. The plurality of second conductive wires 22 is for being electrically coupled between the first leadframe 201 and the source S1 of the first power transistor M1.

The second pin D12 is electrically coupled to the second leadframe 202. The third pin CS′ is for being electrically coupled to the first contact pad 101 of the integrated circuit 10 through the third conductive wire 23. The fourth conductive wire 24 is for being electrically coupled between the first controlling contact pad 103 and the gate G1 of the first power transistor M1. The fifth conductive wire 25 is for being electrically coupled between the second controlling pad 102 of the integrated circuit 10 and the gate G2 of the second power transistor M2. The two grounding pins GND′ are electrically coupled to a grounding contact pad 104 of the integrated circuit 10 through the sixth conductive wire 26. The two power pins VCC′ are adjacent to each other and electrically coupled together (through the conductive wire 28). The two power pins VCC′ are electrically coupled to a power contact pad 105 of the integrated circuit 10 through the seventh conductive wire 27. The two grounding pins GND′ are electrically coupled to the first leadframe 201 through the conductive glue 203. The second pin D12 is electrically coupled to the second leadframe 202 through the conductive glue 204.

Besides, the packaging structure 2 further comprises a packaging body 20 for covering the first leadframe 201, the second leadframe 202, the first power transistor M1, the second power transistor M2, the plurality of first conductive wires 21, the plurality of second conductive wires 22, the third conductive wire 23, the fourth conductive wire 24, the fifth conductive wire 25, the sixth conductive wire 26, the seventh conductive wire 27. The packaging body 20 also partially covers the two grounding pins GND′, the two power pins VCC′, the two first pins BATN, the second pin D12, and the third pin CS′. The packaging body 20 may be made of epoxy molding compound which comprises epoxy, hardener, silicon dioxide, catalyst . . . etc. Usually, the hardener is phenolic resins, and the silicon dioxide has advantage of decreasing the thermal expansion coefficient, and for releasing the mold some was added, but the invention is not restricted thereto.

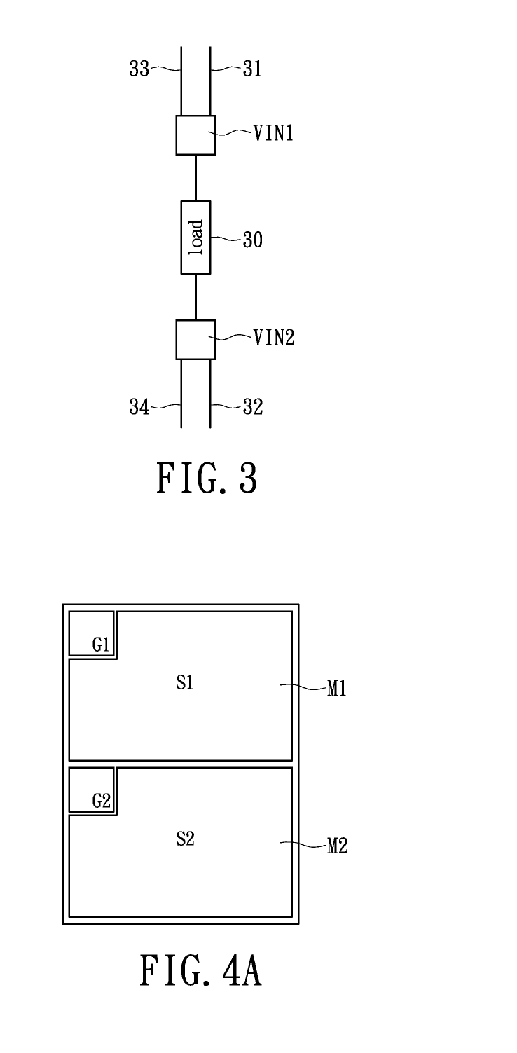

Please refer to FIG. 2D and FIG. 3, FIG. 3 shows a schematic diagram of the four-wire measurement according to an embodiment of the present invention. In the packaging structure 2, the grounding pin GND′ and the first pin BATN′ both have two pins. Therefore, the four-wire measurement may be applied for electronic verification with a large current such as, measurement for the internal resistance of the first power transistor M1 and the second power transistor M2. When the four-wire measurement is applied to a load 30, terminals VIN1, VIN2 both have two pins which are pins 31, 33 and pins 32, 34 respectively. The pins 31, 32 are used for input pins, and the pins 32, 34 are used for measuring pins. According to separation of the input pins and the measuring pins, the measuring error resulted from the additional voltage drop generated by the large current at the wires may be minimized, thus a more accurate measurement result may be obtained.

Please refer to FIG. 2D again; the configuration of the pins is relative to the first to the seventh conductive wire 21˜27. The packaging manner varies according to the single cell lithium-ion battery protection circuit and the power MOSFET, thus the protection circuit for the single cell lithium-ion battery with power transistor can be packaged in a TSSOP-8 package. The embodiment is one of the optimum configurations for packaging.

The number of wires for the plurality of first conductive wires 21 in the packaging structure 2 is corresponding to the internal resistance looked from the first pin BATN′ and the grounding pin GND′. For reducing the internal resistance between the first pin BATN′ and the grounding pin GND′, the bonding manner of these two pins are shown as the configuration of the first to the seventh conductive wire 21˜27 in FIG. 2D. Additionally, the number of wires for the second conductive wire 22 connected to the first leadframe 201 (and electrically coupled to the grounding pin GND′) and the first conductive wire 21 connected to the first pin BATN′ varies due to the packaging structure and the size of the leadframe such as, the number of wires may varies from one to several dozens. Thus, the internal resistance of the first power transistor M1 and the second power transistor M2 may be reduced. In other words, the plurality of first conductive wires 21 and the plurality of second conductive wires 22 are for reducing the internal resistance of the first power transistor M1 and the second power transistor M2.

Please refer to FIG. 1 and FIG. 2D again; the current path in the packaging structure 2 starts from the grounding pin GND′ to the plurality of second conductive wires 22, then the current flows to the controlling terminal (source S1) of the first power transistor M1. Then, the current flows from the first power transistor M1 to the second power transistor M2 through the shared contact pad D12′. Then, the current flows from the source S2 of the second power transistor M2 to the first pin BATN′ through the plurality of first conductive wires 21. In consideration of heat dissipation, if the pin flowing with a large current was connected to the leadframe through conductive glue, the leadframe may benefit heat dissipation.

The packaging structure of this embodiment connects the pin passing with large current to the leadframe through conductive glue. For example, the grounding pin GND′ is connected to the first leadframe 201 by the conductive glue 203 for improving heat dissipation and avoiding the malfunction or damage of the integrated circuit 10 due to overheated. When the lithium-ion battery is charged, the current flows from the grounding pin GND′ to the second pin D12, and then flows to the first pin BATN′. When the lithium-ion battery is discharged, the current flows from the first pin BATN′ to the second D12, and then flows to the grounding pin GND′. The contact pad D12′ of the power transistor and the grounding terminal of the integrated circuit 10 are connected to the second leadframe 202 and the first leadframe 201 through the conductive glue 204 and the conductive glue 203 respectively, thus the first leadframe 201 and the second leadframe 202 may benefit the heat dissipation.

The number of wires for the plurality of first conductive wires 21 and the plurality of second conductive wires 22 influence the internal resistance of the first power transistor M1 and the second power transistor M2. Some numbers of wires are exemplary for describing the influence of the number of wires for the internal resistance. The average resistance of tacking the second pin D12 and the grounding pin GND′ as measuring terminals are 17.39 ohms (the plurality of second conductive wires 22 is six copper wires with 1.5 mils in diameter), 17.91 ohms (the plurality of second conductive wires 22 is five copper wires with 1.5 mils in diameter), 18.68 ohms (the plurality of second conductive wires 22 is four copper wires with 1.5 mils in diameter), wherein the standard deviation is about to 0.3 ohms. The average resistance of tacking the second pin D12 and the first pin BATN′ as measuring terminals are 18.01 ohms (the plurality of first conductive wires 21 is six copper wires with 1.5 mils in diameter), 17.85 ohms (the plurality of first conductive wires 21 is five copper wires with 1.5 mils in diameter), 18.79 ohms (the plurality of first conductive wires 21 is four copper wires with 1.5 mils in diameter), 20.07 ohms (the plurality of first conductive wires 21 is three copper wires with 1.5 mils in diameter). As shown in these examples, the resistance between the source and the drain of the first power transistor M1 and the second power transistor M2 decreases due to increase of the number of conductive wires. In other words, as the number of the plurality of first conductive wires 21 and the plurality of second conductive wires 22 increases, the internal resistance is lowered correspondingly. Besides, for a lower resistance, the diameter of the copper used for the plurality of first conductive wires 21 and the plurality of second conductive wires 22 may be 1.5˜2 mils.

[Another Embodiment of the Packaging Structure]

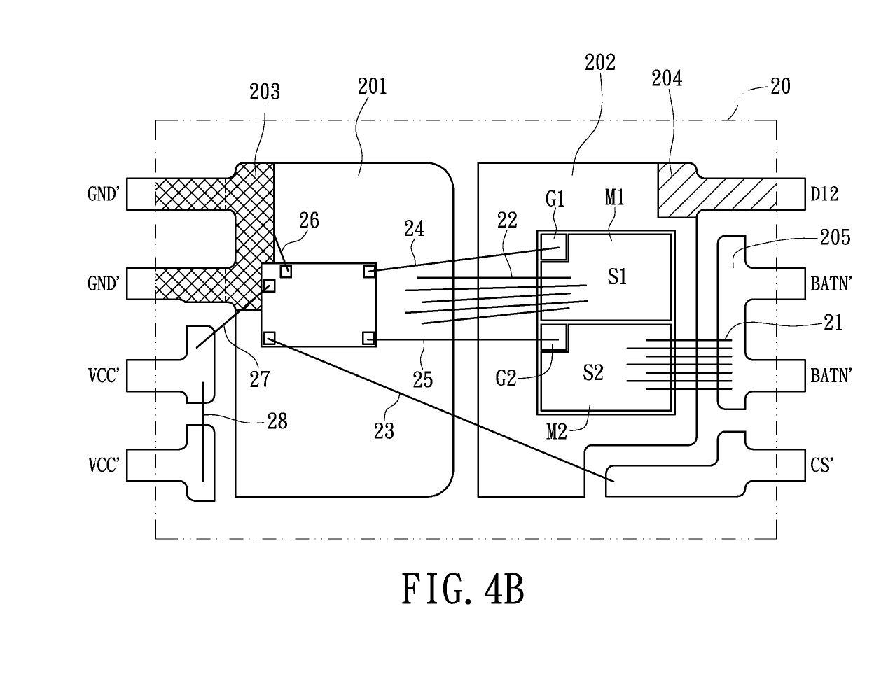

Please refer to FIG. 4A and FIG. 4B, FIG. 4A shows a top view of pins of a first power transistor and a second power transistor according to another embodiment of the present invention, and FIG. 4B shows a perspective diagram of a packaging structure according to another embodiment of the present invention. The packaging structure 4 mainly comprises a first leadframe, a second leadframe 202, two grounding pins GND′, two first pins BATN′, a plurality of first conductive wires 21, a plurality of second conductive wires 22, and conductive glue 203, 204. Additionally, the packaging structure 4 further comprises two power pins VCC′, the second pin D12, the third pin CS′, a third conductive wire 23, a fourth conductive wire 24, a fifth conductive wire 25, a sixth conductive wire 26, a seventh conductive wire 27, and a conductive wire 28.

The packaging structure 4 of the embodiment is significantly identical to the packaging structure 2 of the previous embodiment (shown in FIG. 2D) except for differences specified in the follows. The positions of the sources S1, S2 and the gates G1, G2 of the first power transistor M1 and the second power transistor M2 shown in FIG. 4A are not distant from each other. Additionally, the gates G1, G2 may be adjacent to each other. However, when the positions of the gates G1, G2 are determined, the second conductive wire 22 may not across the fourth conductive wire 24 for reducing the length of the second wire 22, thus the resistance may also be reduced. Other description of the packaging structure 4 for this embodiment can be referred to the description in the previous embodiment, thus the redundant information is not repeated.

According to embodiments of the present invention, the packaging structure can simplified the traditional protection circuit for the single cell lithium-ion battery. The packaging structure is convenient to utilize the four-wire measurement, and the internal resistance of the power transistors is lowered. The associated cost may be cut down by packaging the power transistors with the integrated circuit. Therefore, the mentioned packaging structure is more competitive in the market.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. A packaging structure, comprising:
a first leadframe, for disposing an integrated circuit;
a second leadframe, for disposing a first power transistor and a second power transistor, and for being electrically coupled to drains of the first power transistor and the second power transistor;
two grounding pins, electrically coupled to the first leadframe, and the two grounding pins being adjacent to each other;
two first pins, for being electrically coupled to a source of the second power transistor, the two first pins connecting to each other through a conductive region, wherein the conductive region is for increasing the capacity of the current loading of the two first pins;
a plurality of first conductive wires, for being electrically coupled between a source of the second power transistor and the two first pins, for reducing the internal resistance of the second power transistor;
a plurality of second conductive wires, for being electrically coupled between the first leadframe and a source of the first power transistor, for reducing the internal resistance of the first power transistor; and
a packaging body, for covering the first leadframe, the second leadframe, the plurality of first conductive wires, the plurality of second conductive wires, the integrated circuit, the first power transistor, and the second power transistor, and partially covering the two grounding pins and the two first pins.

2. The packaging structure according to claim 1, further comprising:
a second pin, electrically coupled to the second leadframe; and
a third pin, for being electrically coupled to a first contact pad of the integrated circuit through a third conductive wire.

3. The packaging structure according to claim 2, further comprising:
a fourth pin, for being electrically coupled between a first controlling contact pad of the integrated circuit and a gate of the first power transistor; and
a fifth pin, for being electrically coupled between a second controlling contact pad of the integrated circuit and the gate of the second power transistor.

4. The packaging structure according to claim 1, wherein the diameter of the plurality of first conductive wires and the plurality of second conductive wires is between 1.5 and 2 mils.

5. The packaging structure according to claim 3, wherein the two grounding pins are electrically coupled to a grounding contact pad of the integrated circuit through a sixth conductive wire.

6. The packaging structure according to claim 5, wherein the two power pins are electrically coupled to a power contact pad of the integrated circuit through a seventh conductive wire.

7. The packaging structure according to claim 2, wherein the two power pins are adjacent to each other and electrically coupled together.

8. The packaging structure according to claim 1, wherein the two grounding pins are electrically coupled to the first leadframe through conductive glue.

9. The packaging structure according to claim 2, wherein the second pin is electrically coupled to the second leadframe through conductive glue.

10. The packaging structure according to claim 6, wherein the packaging structure is a thin-shrink small-outline package with eight pins (TSSOP-8).
